(19) United States
(12) Patent Application Publication
(10) Pub. No.: US 2024/0140864 A1
(43) Pub. Date: May 2, 2024

(54) 3D INTERPOSER WITH THROUGH GLASS VIAS - METHOD OF INCREASING ADHESION BETWEEN COPPER AND GLASS SURFACES AND ARTICLES THEREFROM

(71) Applicant: CORNING INCORPORATED, CORNING, NY (US)

(72) Inventors: Hoon Kim, Horseheads, NY (US); Prantik Mazumder, Ithaca, NY (US); Aram Rezikyan, Painted Post, NY (US); Rajesh Vaddi, Horseheads, NY (US)

(21) Appl. No.: 18/409,103

(22) Filed: Jan. 10, 2024

Related U.S. Application Data
(63) Continuation of application No. 16/666,876, filed on Oct. 29, 2019, now abandoned.
(60) Provisional application No. 62/760,406, filed on Nov. 13, 2018.

(51) Int. Cl. C03C 27/04; C03C 17/245; C03C 17/36

(52) U.S. Cl. CPC C03C 27/048; C03C 17/245; C03C 17/3607; C23C 18/1637

(57) ABSTRACT

In some embodiments, a method comprises: depositing an adhesion layer comprising manganese oxide (MnOₓ) onto a surface of a glass or glass ceramic substrate; depositing a first layer of conductive metal onto the adhesion layer; and annealing the adhesion layer in a reducing atmosphere. Optionally, the method further comprises pre-annealing the adhesion layer in an oxidizing atmosphere before annealing the adhesion layer in a reducing atmosphere.

This application is a continuation of and claims the benefit of priority of U.S. patent application Ser. No. 16/666,876, filed on Oct. 29, 2019, which claims the benefit of priority to U.S. Provisional Application No. 62/760,406 filed on Nov. 13, 2018, the contents of which are incorporated herein by reference in their entirety.

### FIELD

This description pertains to glass surfaces and articles having improved adhesion to copper.

### BACKGROUND

Glass and glass ceramic substrates with vias are desirable for many applications, including for use as in interposers used as an electrical interface, RF filters, and RF switches. Glass substrates have become an attractive alternative to silicon and fiber reinforced polymers for such applications. But, it is desirable to fill such vias with copper, and copper does not adhere well to glass. In addition, a hermetic seal between copper and glass is desired for some applications, and such a seal is difficult to obtain because copper does not adhere well to glass.

Accordingly, a need exists for methods of better adhering copper to glass and glass ceramic materials.

### SUMMARY

In a 1st aspect, a method comprises: depositing an adhesion layer comprising manganese oxide (MnOₓ) onto a surface of a glass or glass ceramic substrate; depositing a catalyst for electroless copper deposition onto the adhesion layer; depositing by electroless plating a first layer of copper onto the MnOₓ layer, after depositing the catalyst; and annealing the adhesion layer in a reducing atmosphere.

In a 2^{nd} aspect, for the 1^{st} aspect, the adhesion layer is deposited by chemical vapor deposition or atomic layer deposition.

In a 3rd aspect, for any of the 1^{st} and 2^{nd} aspects, the adhesion layer consists essentially of MnOₓ.

In a 4^{th} aspect, for any of the P t and 2^{nd} aspects, the adhesion layer consists of MnOₓ.

In a 5^{th} aspect, for any of the 1^{st} and 2^{nd} aspects, the adhesion layer comprises 50 at % Mn or more, excluding oxygen.

In a 6^{th} aspect, for any of the 1^{st} through 5^{th} aspects, the adhesion layer is annealed in a reducing atmosphere before depositing the catalyst.

In a 7^{th} aspect, for any of the 1^{st} through 5^{th} aspects, the adhesion layer is annealed in a reducing atmosphere after depositing the catalyst.

In a 8^{th} aspect, for any of the 1^{st} through 5^{th} aspects, the adhesion layer is annealed in a reducing atmosphere after depositing the first layer of copper.

In a 9^{th} aspect, for any of the 1^{st} through 8^{th} aspects, the annealing in a reducing atmosphere is performed at a temperature of 200° C. or greater in an atmosphere containing 1% or more by volume of a reducing agent.

In a 10^{th} aspect, for any of the 1^{st} through 9^{th} aspects, the method further comprises pre-annealing the adhesion layer in an oxidizing atmosphere before annealing the adhesion layer in a reducing atmosphere.

In a 11^{th} aspect, for any of the 1^{st} through 10^{th} aspects, the adhesion layer after annealing includes a layer of MnOₓ having a thickness of 3 nm or more.

In a 12^{th} aspect, for the 11^{th} aspect, the adhesion layer after annealing includes a layer of MnOₓ having a thickness of 6 nm or more.

In a 13^{th} aspect, for the 12^{th} aspect, the adhesion layer after annealing includes a layer of MnOₓ having a thickness of 6 nm to 9 nm.

In a 14^{th} aspect, for any of the 1^{st} through 13^{th} aspects, the surface is an interior surface of a via hole formed in the glass or glass ceramic substrate.

In a 15^{th} aspect, for the 14^{th} aspect, the via is a through via.

In a 16^{th} aspect, for the 14^{th} aspect, the via is a blind via.

In a 17^{th} aspect, for any of the 1^{st} through 14^{th} aspects, the surface is an interior surface of a trench.

In a 18^{th} aspect, for any of the 1^{st} through 14^{th} aspects, the surface is a patterned portion of a planar portion of the substrate.

In a 19^{th} aspect, for any of the P t through 18^{th} aspects, the adhesion layer is conformally deposited.

In a 20^{th} aspect, for any of the P t through 18^{th} aspects, the adhesion layer is not conformally deposited.

In a 21^{st} aspect, for any of the 1^{st} through 20^{th} aspects, the adhesion layer is deposited by ALD.

In a 22^{nd} aspect, for any of the 1^{st} through 20^{th} aspects, the adhesion layer is deposited by CVD.

In a 23^{rd} aspect, for any of the 1^{st} through 22^{nd} aspects, the method further comprises: depositing a second layer of copper, by electrolytic plating, over the first layer of copper.

In a 24^{th} aspect, for the 23rd aspect, the second layer of copper has a thickness of 2 μm or more.

In a 25^{th} aspect, for any of the 23rd through 24th aspects, the second layer of copper is capable of passing a 5N/cm tape test.

In a 26^{th} aspect, for any of the 1^{st} through 25th aspects, the glass or glass ceramic substrate comprises a material having a bulk composition, in mol % on an oxide basis, of 50% to 100% SiO₂.

In a 27^{th} aspect, for any of the 1^{st} through 26th aspects, depositing a catalyst comprises:
charging the adhesion layer by treating with aminosilanes or nitrogen-containing polycations;
after charging, adsorbing palladium complexes onto the adhesion layer by treatment with a palladium-containing solution.

In a 28^{th} aspect, a method comprises:
depositing an adhesion layer comprising manganese oxide (MnOₓ) onto a surface of a glass or glass ceramic substrate;
depositing a first layer of conductive metal onto the adhesion layer; and
annealing the adhesion layer in a reducing atmosphere.

The 28^{th} aspect may be combined in any permutation with any of the 1^{st} through 27 aspects.

In a 29^{th} aspect, for the 28^{th} aspect, the adhesion layer is annealed after depositing the first layer of conductive metal.

In a 30^{th} aspect, for any of the 28^{th} through 29^{th} aspects, the adhesion layer is deposited by chemical vapor deposition or atomic layer deposition.

In a 31^{st} aspect, for any of the 28^{th} through 30^{th} aspects, the method further comprises pre-annealing the adhesion layer in an oxidizing atmosphere before annealing the adhesion layer in a reducing atmosphere.

In a 32^{nd} aspect, for any of the 28^{th} through 31^{st} aspects, the surface is an interior surface of a via hole formed in the glass or glass ceramic substrate.

In a 33^{rd} aspect, an article comprises:
a glass or glass ceramic substrate having a plurality of vias formed therein, each via having an interior surface;
a layer of MnOₓ bonded to the interior surface, wherein the layer of MnOₓ has a thickness of at least 3 nm;
a layer of copper bonded to the layer of MnOₓ.

The 33^{rd} aspect may be combined with any of the 1^{st} through 32^{nd} aspects in any permutation.

In a 34^{th} aspect, for the 33^{rd} aspect, the copper filling the via is capable of passing a 5N/cm tape test.

### BRIEF DESCRIPTION OF THE DRAWINGS

FIG. 1 shows a substrate having through via holes.

FIG. 2 shows a substrate having blind via holes.

FIG. 3. shows a filled through via hole with a MnOₓ adhesion layer.

FIG. 4. shows a process flow.

FIG. 5 shows Transmission Electron Microscopy (TEM) images of two Examples, one exposed to a reducing anneal and the other not.

FIG. 6 shows TEM images of two Examples, one exposed to a reducing anneal and the other not, with superimposed composition data.

FIG. 7 shows TEM images similar to FIG. 6, but at different locations on the Examples.

### DETAILED DESCRIPTION

Glass and glass ceramic substrates with vias are desirable for a number of applications. For example, 3D interposers with through package via (TPV) interconnects that connect the logic device on one side and memory on the other side are desirable for high bandwidth devices. The current substrate of choice is organic or silicon. Organic interposers suffer from poor dimensional stability while silicon wafers are expensive and suffer from high dielectric loss due to semiconducting property. Glass may be a superior substrate material due to its low dielectric constant, thermal stability, and low cost. There are applications for glass or glass ceramic substrates with through vias or blind vias. These via holes typically need to be fully or conformally filled by conducting metals such as copper to form a via that provides an electrical pathway. Copper is a particularly desirable conducting metal. The chemical inertness and low intrinsic roughness of glass and glass ceramic materials, however, pose a problem related to adhesion of the copper to the glass wall inside the vias. Lack of adhesion between copper and glass could lead to reliability issues such as cracking, delamination, and a path for moisture and other contaminants along the glass-copper interface. Described herein are approaches to increase the effective adhesion between copper and glass or glass ceramic materials on any glass or glass ceramic surface, including the interior surface of via holes as well as other surfaces.

In some embodiments, a layer comprising MnOₓ is used as an adhesion layer to promote the adhesion of copper or other conductive metal to glass. Annealing the layer of MnOₓ under a reducing atmosphere as described herein results in surprisingly superior adhesion. Without being limited by theory, it is believed that such annealing results in a gradient in the MnOₓ layer, with relatively oxygen-rich regions near the glass, and relatively oxygen poor regions near the copper. The oxygen-rich regions, with a higher oxidation state for Mn, is more oxide in character and can form oxide-oxide bonds with a glass or dielectric coated substrate. The oxygen-poor regions, with a lower oxidation state for the Mn, is more metallic in character, and can form metallic bonds with copper or other conductive metals. As a result, a copper layer can be bonded to glass with an adhesion sufficient to pass a 5 N/cm adhesion test.

Without being limited by theory, it is believed that a weak link in adhering copper and similar metals to glass is difficulty in bonding metal to oxide. So, when using an oxide adhesion layer, the weakest link in the system is believed to be the interface between the oxide adhesion layer and the copper. It is believed that annealing the MnOₓ adhesion layer, when in contact with copper, under a reducing atmosphere as described herein results in a stronger MnOₓ— copper interface. In experiments described herein, such annealing resulted in better adhesion. In some experiments, a layer of MnOₓ remains adjacent to the copper after such annealing, and a large amount of MnO is detected near the copper-MnOₓ interface. Copper adheres better to MnO than to more oxidized forms of MnOₓ, so the MnO layer may explain the superior adhesion. But, in other experiments, such annealing resulted in better adhesion, but there was no discrete observable layer of MnOₓ adjacent to the copper, and any MnO present was not enough to detect directly using the methodologies described herein. But, based on the superior adhesion observed and the observation of MnO in some experiments, it is believed that the annealing creates MnO at the interface, which improves bonding of copper to MnOₓ to copper. While most of the Mn may diffuse into the glass or copper depending on annealing and sample conditions, it is believed that some Mn in the MnO oxidations state remains at the interface to enhance adhesion.

Substrates with Vias

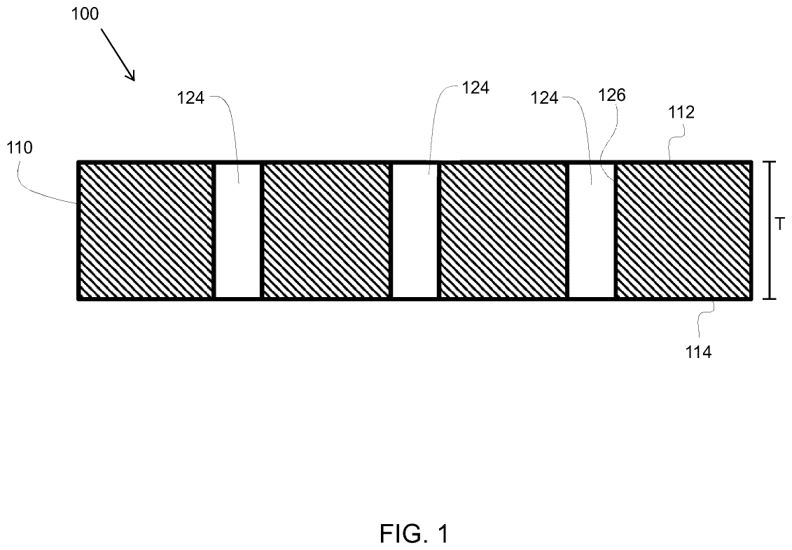

FIG. 1 shows a cross section of an example article 100. Article 100 includes a substrate 110. Substrate 110 has a first surface 112 and a second surface 114, separated by a thickness T. A plurality of via holes 124 extend from first surface 112 to second surface 114, i.e., via holes 124 are through via holes. Interior surface 126 is the interior surface of via 124 formed in substrate 110.

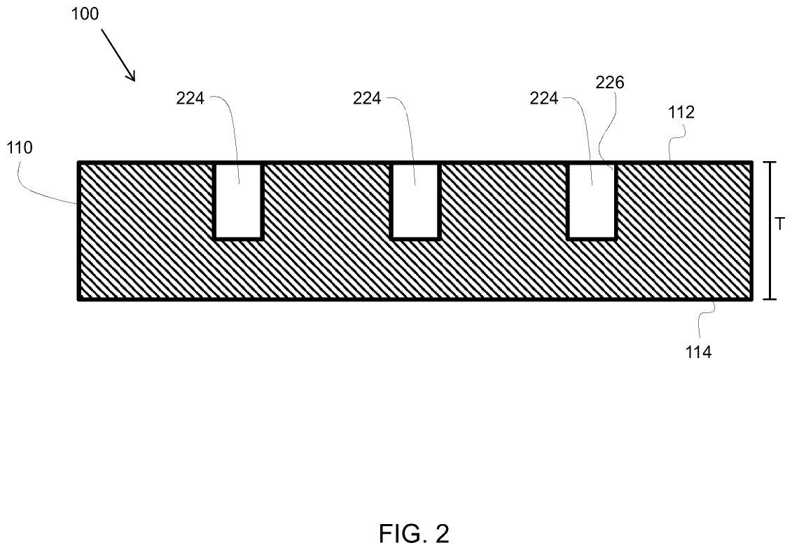

FIG. 2 shows a cross section of an example article 200. Article 200 includes a substrate 110. Substrate 110 has a first surface 112 and a second surface 114, separated by a thickness T. A plurality of via holes 224 extend from first surface 112 towards second surface 114, without reaching second surface 114, i.e., via holes 124 are blind vias. Surface 226 is the interior surface of via 224 formed in substrate 110.

While FIG. 1 and FIG. 2 show specific via hole configurations, various other via hole configurations may be used. By way of non-limiting example, vias having an hourglass shape, a barbell shape, beveled edges, or a variety of other geometries may be used instead of the cylindrical geometries shown in FIGS. 1 and 2. The via hole may be substantially cylindrical, for example having a waist (point along the via with the smallest diameter) with a diameter that is at least 70%, at least 75%, or at least 80% of the diameter of an opening of the via on the first or second surface. The via hole may have any suitable aspect ratio. For example, the via hole may have an aspect ratio of 1:1, 2:1, 3:1, 4:1, 5:1, 6:1, 7:1, 8:1, 9:1, 10:1, or any range having any two of these values as endpoints, or any open-ended range having any of these values as a lower bound. Other via geometries may be used.

### Glass Composition

In the most general sense, any suitable glass or glass-ceramic composition in which via holes can be formed may be used. Exemplary compositions include high purity fused silica (HPFS), and aluminoborosilicate glasses. High silica glasses are particularly problematic for bonding with metals in the absence of embodiments described herein. In some embodiments, the glass or glass ceramic has 50 wt % or more, 60 wt % or more, 70 wt % or more, 80 wt % or more, 90 wt % or more, or 95 wt % or more silica content by weight on an oxide basis.

### MnOₓ Adhesion Layer

Prior to depositing a conductive metal such as copper, an adhesion layer comprising MnOₓ is deposited over the glass. This adhesion layer, after annealing with a reducing atmosphere as described herein, will adhere well to both the glass over which it is deposited and to a subsequently deposited conductive metal, such as copper.

The adhesion layer can have any composition that includes sufficient MnOₓ to bond to both glass and copper or other metal as described herein. The adhesion layer may consist essentially of MnOₓ, or may have other components. For example, the adhesion layer may comprise MnSiOₓ. In some embodiments, the adhesion layer is 20 at % to 100 at % Mn, or 20 at % to 90 at % Mn, excluding oxygen. In some embodiments, the adhesion layer is 50 at % Mn or more, excluding oxygen. As used herein, the at % evaluation “excluding oxygen” means that the at % is determined based on all components of the layer other than oxygen. So, a layer of pure MnOₓ would have 100 at % Mn excluding oxygen, regardless of oxidation state.

The MnOₓ adhesion layer may be deposited by any suitable process. Suitable processes include chemical vapor deposition (CVD), atomic layer deposition (ALD), sputtering with long-through, re-sputtering method and e-beam evaporation. Where deposition is desired for non-planar geometries, such as the inside surface of a via, techniques such as CVD and ALD that do not rely on line of sight to a source may be used. Techniques that do rely on line of sight to a source, such as various types of sputtering and e-beam evaporation, may be used to achieve non-uniform deposition on non-planar geometries, such as deposition of adhesion layer only near the openings of a via but not in the middle portion. Techniques relying on line of sight to a source may also be used to achieve conformal deposition on sufficiently small planar surfaces. Techniques such as CVD and ALD may be used to achieve conformal deposition over large areas, including non-planar areas such as the interior surface of a via hole. As used herein, a “conformal” layer has uniform thickness.

Depending on deposition techniques and parameters, the MnOₓ adhesion layer may be deposited in some locations but not others. For example, conformal deposition techniques may be used to deposit the MnOₓ layer everywhere on an interior via surface. Or, a line-of-sight deposition technique combined with specific substrate orientations and rotation may be used to deposit the MnOₓ adhesion layer, for example, on the interior via surface only near the opening of the via.

Various precursors are possible to deposit MnO. (EtCp)2Mn, Mn(thd; 2,2,6,6-tetramethylheptan-3,5-dione)3, Mn amidinate(Bis(N,N′-di-i-propylpentylamidinato)manganese(II), Bis(pentamethylcyclopentadienyl)manganese(II), Bis(tetramethylcyclopentadienyl) manganese(II), Cyclopentadienylmanganese(I) tricarbonyl, Ethylcyclopentadienylmanganese(I) tricarbonyl,Manganese(0) carbonyl or similar metal organic compounds or halides containing manganese precursors may be used to deposit manganese oxide.

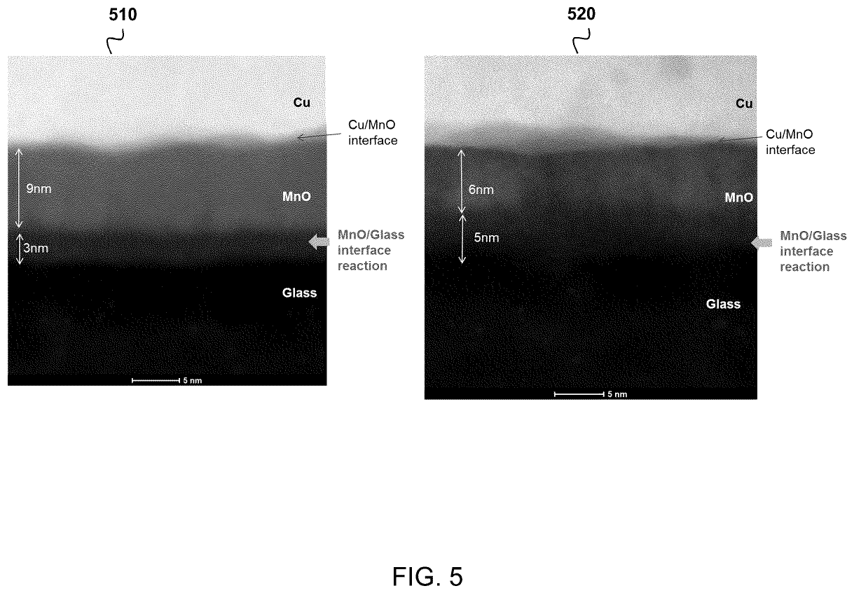

The MnOₓ adhesion layer can have any suitable thickness. In some embodiments, the MnOₓ adhesion layer has a thickness of 1 nm, 2 nm, 4 nm, 6 nm, 8 nm, 10 nm, 15 nm, 20 nm, 25 nm, 50 nm, 100 nm or any range having any two of these values as endpoints. In some embodiments, the MnOₓ adhesion layer has a thickness of 4 nm to 20 nm, or 6 nm to 15 nm. Other thicknesses may be used. As used herein, the thickness of the MnOₓ layer does not include an intermixing layer, such as that shown in FIG. 5. Unless otherwise specified, the thickness of an MnOₓ layer, may be measured by observing interfaces visible in a TEM image and determining the composition of the layer at various points using Electron Energy Loss Spectroscopy (EELS).

As deposited, the MnOₓ adhesion layer may have any suitable oxygen content. In some embodiments, MnOₓ is deposited by PVD, and the oxidation state as deposited is Mn₃O₄. The oxidation state may be subsequently modified by exposure to oxidizing and/or reducing atmospheres as described herein. The method of claim 1, wherein the adhesion layer comprises 20 at % or more, 50 at % or more, or 80 at % or more (where at % means atomic %) Mn excluding oxygen.

### Pre Anneal

Prior to annealing under a reducing atmosphere, a high oxidation state adjacent the glass may be achieved by one or more of: a suitable deposition technique, and pre-annealing in an oxidizing atmosphere. This pre-anneal is technically an annealing step in the sense that the word “anneal” is generally used to describe thermal treatment that changes microstructure. But herein, “pre-anneal” is used to describe thermal treatment prior to annealing under a reducing atmosphere to avoid confusion between “pre-annealing” under an oxidizing atmosphere and “annealing” under a reducing atmosphere. Pre-annealing the MnOₓ adhesion layer and subsequently annealing allows for the formation of an oxidation (and oxidation state) gradient across the MnOₓ adhesion layer. The pre-anneal (oxidizing) achieves/preserves a high oxidation state in the MnOₓ layer adjacent to the glass, which adheres well to glass. And, the anneal (reducing) achieves a low oxidation state in the MnOₓ layer adjacent the copper, which adheres well to copper. In some embodiments, the combination of pre-anneal (or deposition conditions) and anneal results in an MnOₓ layer with a gradient in oxidation state from glass to copper. In some embodiments, the MnOₓ layer may be consumed during the anneal, likely by Mn diffusion into glass and/or copper. But, without being limited by theory, it is believed that some residual MnOₓ remains behind after such diffusion at the copper—glass interface in oxidation states suitable to enhance adhesion at that interface.

The optional pre-anneal may be performed at any time after the MnOₓ adhesion layer is deposited and before the anneal under a reducing atmosphere. Performing the pre-anneal before the MnOₓ adhesion layer is deposited would not have the desired effect of oxidizing the MnOₓ adhesion layer adjacent to the glass. The optional pre-anneal may be performed any time before annealing the MnOₓ adhesion layer. In some embodiments, it is preferred to perform the optional pre-anneal after depositing the MnOₓ adhesion layer, and prior to initiating deposition of metal such as copper, and related steps such as depositing catalyst. Performing the pre-anneal at this time allows for the desired effect of oxidizing the MnOₓ adhesion layer adjacent to the glass, without interfering with the results of other processes.

Any suitable pre-anneal temperature may be used, where “suitable pre-anneal temperature” means that the pre-anneal oxidizes the MnOₓ adhesion layer at the temperature. In some embodiments, the annealing temperature is 200° C., 250° C., 300° C., 350° C., 400° C., 450° C., 500° C., 550° C., 600° C., or any range having any two of these values as endpoints. In some embodiments, the annealing temperature is 200° C. to 600° C., 300° C. to 500° C., or 350° C. to 450° C. Annealing at too high a temperature may lead to undesirable effects such as damage to the MnOₓ layer or underlying substrate. Annealing at too low a temperature may lead to oxidation of the MnOₓ adhesion layer at rates too slow to be commercially practical.

Any suitable pre-anneal atmosphere may be used, where “suitable pre-anneal atmosphere” means that the pre-anneal oxidizes the MnOₓ adhesion layer in the temperature range 200° C. to 600° C. Most oxygen-containing atmospheres are suitable. In some embodiments, ambient conditions are preferred due to low cost.

### Metal Deposition Generally

A conductive metal, such as copper, may be deposited over the MnOₓ adhesion layer. Any suitable deposition process may be used. For filling vias, it is desirable to use processes that do not rely on line of sight to deposit copper. For example, electroless and electroplating may be used. Electroplating is a desirable technique for filling vias, because it does not rely on line of sight to a deposition source. But, electroplating relies upon a previously deposited Techniques that rely on line of sight, such as physical vapor deposition (PVD), may encounter difficulty in filling a via hole for any of the deposited layers (e.g., MnOₓ adhesion layer, copper seed layer for subsequent electroplating, etc.)

### Catalyst

In some embodiments, electroless deposition is used to deposit copper. Copper deposits by electroless deposition at a much faster rate where a catalyst is present. One suitable process flow for electroless deposition of copper is:
Treat surface with aminosilanes or nitrogen-containing polycations;
Adsorb palladium complexes by treatment with a palladium-containing solution;
Deposit electroless copper

Before depositing metal by electroless deposition, the substrate may optionally be treated with aminosilanes or nitrogen containing polycations. A catalyst may optionally be subsequently deposited. The treatment with aminosilanes or nitrogen containing polycations produces a cationic charge state of the glass surface, which enhances catalyst adsorption. The catalyst adsorption step entails treatment of the glass surface, for example, with K₂PdCl₄ or ionic palladium or Sn/Pd colloidal solutions. The palladium complexes usually exist in anionic form and, therefore, their adsorption on the glass surface is enhanced by the cationic surface groups such as protonated amines. If K₂PdCl₄ or ionic palladium chemistries are used, the next step involved reduction of the palladium complex into metallic palladium, Pd(0), preferably (but not limited to) in the form of colloids of dimension ˜2-10 nm. If Sn/Pd colloidal solution is used, the palladium is already in Pd(0) form with a Sn shell around it which is removed by acid etching.

### Thin First Layer of Copper or Other Metal

In some embodiments, a thin first layer of conductive metal such as copper is deposited over the MnOₓ adhesion layer. Electroless deposition is slow relative to electroplating. But, electroless deposition can be performed on non-conductive surfaces, whereas electroplating is limited to conductive surfaces. For depositing on the inner surface of a via, electroless deposition favorably does not rely on line of sight. Atomic Layer Deposition (ALD) is another suitable method to deposit a thin first layer of copper that does not rely on line of sight. It has been observed that these techniques that do not rely on direct line of sight may result in inferior adhesion compared to some techniques that do rely on direct line of sight, such as physical vapor deposition (PVD). Without being limited by theory, it is believed that line of sight deposition techniques may involve more kinetic energy during deposition, which may result in the formation of bonds between copper and the MnOₓ adhesion layer, and possibly changes in the oxidation state of MnOₓ.

In some embodiments, techniques that do rely on line of sight may be used to deposit a thin first layer of conductive metal. These techniques may be difficult to use when adhering copper to the interior surface of a via, because line of sight may not work well with vias. The issue may be particularly exacerbated with vias having a high aspect ratio, such as 3:1 or greater, 4:1 or greater, 5:1 or greater, 6:1 or greater, 8:1 or greater, or 10:1 or greater. But, it has been observed that, depending on deposition conditions, depositing a first (seed) layer of copper by PVD may result in the formation of some MnO. In this case, adhesion may be superior to that seen with a first layer of copper deposited by techniques that do not rely on line of sight, such as electroless deposition, CVD and ALD. But, annealing under a reducing atmosphere may improve adhesion regardless of the technique used to deposit the seed layer.

Any suitable thickness may be used for a first layer of copper or other metal deposited by electroless deposition. In some embodiments, where the goal of electroless deposition is to enable electroplating, the first layer should have a thickness sufficient to provide the conductivity used for electroplating. For example, the sheet resistance of electroless copper deposited to a thickness of 150 nm is less than 1 Ohm/sq, which is sufficient to serve as a conductive seed for electroplating. In some embodiments, the first layer has a thickness of 50 nm, 100 nm, 150 nm, 200 nm, 250 nm, 300 nm, 400 nm, 500 nm, 1000 nm, or any range having any two of these values as endpoints. In some embodiments, the first layer has a thickness of 50 nm-1000 nm, 100 nm-500 nm, or 100 nm-200 nm.

### Thicker Second Layer of Copper or Other Metal by Electroplating

In some embodiments, if faster deposition of a thicker copper layer is desired, electroless deposition of a first layer of copper may optionally be followed by electroplating a second, thicker layer of copper. Electroless deposition has certain advantages, such as the ability to deposit onto an initially non-conductive surface. But, electroless plating can be slow where thick layers are desired. Once an initial layer of electroless copper is deposited to form the conductive surface used in electroplating, electroplating may be used to more quickly deposit a thicker layer of copper. The total thickness of copper may be any desired thickness.

For forming vias in via holes, the total thickness of copper is a function via hole geometry and desired via geometry. For example, if it is desired to completely fill a hole, the total thickness of copper should be the radius of the via hole. If a conductive conformal coating of copper is desired, the total thickness should be less than the total thickness of the hole, but sufficiently thick to attain a desired conductivity. In some embodiments, the second layer has a thickness of 1 μm, 2 μm, 3 μm, 4 μm, 5 μm, 10 μm, 15 μm, 20 μm, 30 μm, 50 μm, 100 μm, or any range having any two of these values as endpoints, or any open ended range having one of these values as the lower end-point. In some embodiments, the second layer has a thickness in the range 1 μm to 100 μm, 1 μm to 20 μm, 3 μm to 15 μm, or 2 μm or greater.

### Annealing Under Reducing Atmosphere

In some embodiments, the MnOₓ layer is annealed under a reducing atmosphere. In the experiments described herein, this annealing used forming gas with a 4% hydrogen content (nitrogen with 4% hydrogen by volume). But, other reducing atmospheres may be used, including forming gas with a different percentage of hydrogen, and alternate gas compositions. As used herein, a “reducing atmosphere” is an atmosphere that extracts oxygen from MnOₓ for at least one annealing temperature in the temperature range 200° C.-600° C. In some embodiments, the reducing atmosphere comprises 1% or more by volume H₂ or similar reducing agent, and exposure to the reducing atmosphere is at a temperature of 200° C. or higher. It is preferred to use a reducing atmosphere that extracts oxygen as least as strongly as forming gas, and more preferably at least as strongly as forming gas with 4% hydrogen content.

Any suitable annealing temperature may be used, where “suitable annealing temperature” means that the annealing extracts oxygen from the MnOₓ adhesion layer at the temperature. In some embodiments, the annealing temperature is 200° C., 250° C., 300° C., 350° C., 400° C., 450° C., 500° C., 550° C., 600° C., or any range having any two of these values as endpoints. In some embodiments, the annealing temperature is 200° C. to 600° C., 200° C. to 400° C., or 300° C. to 400° C. Annealing at too high a temperature may lead to undesirable effects such as the agglomeration of copper and undesirable stress. In some embodiments, the annealing temperature is 400° C. or less to avoid such agglomeration, although higher temperatures may be used in some instances, for example, with thicker copper layers. Annealing at too low a temperature may lead to extraction of oxygen from the MnOₓ adhesion layer at rates too slow to be commercially practical.

Manganese oxide is stable in a wide variety of oxidation states, in MnO, Mn₃O₄, Mn₂O₃, and MnO₂. Manganese oxide in any of its oxidation states, including mixtures thereof, are considered “manganese oxide” or “MnOₓ”. For the portion of an adhesion layer touching glass, higher oxidation states of MnOₓ are preferred, such as MnO₂, to form a strong bond with the glass. But, these high oxidation states form a poor bond with copper and other conductive metals such as silver and gold. Lower oxidation states, such as MnO, are desirable for a portion of an adhesion layer touching such a conductive metal, to form a strong bond with the metal. But, these low oxidation states form a poor bond with glass.

Some embodiments described herein describe adhesion layers having a gradient in the oxide state of MnOₓ across the adhesion layer, from low (e.g., a measurable layer of MnO) adjacent to the metal to higher adjacent to the glass. Some embodiments described herein also teach how to achieve such gradient structures by annealing in a reducing atmosphere to achieve a low oxidation state adjacent to the metal. The parameters and kinetics of such annealing may be selected to reduce the oxidation state of the MnOₓ to a greater extent closer to the conductive metal, and to a lesser extent closer to the glass.

Some embodiments described herein describe adhesion layers that do not have a measurable discrete layer of MnOₓ adjacent to the metal remaining after the processing is complete. Without being limited by theory, it is believed that annealing under a reducing atmosphere may, in some embodiments, change the nature of the interface and increase bond strength between the metal layer and the MnOₓ adhesion layer without creating a measurable layer of MnOₓ. In such embodiments, the physical change in the nature of the interface between the MnOₓ adhesion layer and the metal layer may be difficult to directly observe. But, the physical change is measurable, for example, by tape test such as 5N/cm tape test, based on the reasonable assumption that the MnOₓ— metal interface is where failure occurs in an un-annealed sample. Without being limited by theory, the physical difference may be a region of intermixing between copper and glass resulting from diffusion away of Mn, and/or bonding mediated by Mn.

Some benefit may be obtained by annealing the MnOₓ adhesion layer at any time after it is deposited. For example, the MnOₓ adhesion layer may be annealed: (1) immediately after it is deposited and before any other steps are performed (if there is no oxidizing pre-anneal); (2) after an optional pre-anneal and before any other layers are deposited; (3) after a catalyst is deposited and before copper (or other metal) is deposited; (4) after a thin first layer of copper is deposited, for example by electroless plating; or (5) after a thick second layer of copper is deposited, for example by electroplating. In some embodiments, it is preferred to anneal under a reducing atmosphere after the thin first layer of copper is deposited, and before the thick second layer of copper is deposited. Hydrogen is a small molecule, which can penetrate copper to reach the MnOₓ adhesion layer. This penetration is consistent with experimental results described herein, where annealing under forming gas after electroless copper deposition results in improved adhesion and noticeable differences in the microstructure of the MnOₓ adhesion layer. Annealing after the first layer of copper is present allows MnOₓ, when it is reduced to an oxidation state that bonds well with copper such as MnO or even Mn, to immediately do so without time for interfering mechanisms to occur. Beneficial effect may occur after depositing a thicker second layer of copper. But, it may be more difficult for the hydrogen to reach the adhesion layer through the second layer, depending on the thickness of the second layer and the overall article geometry. Beneficial effects may also occur if the reducing anneal is performed before copper is present, in that the reducing anneal may create lower oxidation states of MnOₓ that will adhere better to copper. But, it is preferred to anneal under reducing atmosphere after copper is present so that bonding with lower oxidation states of MnOₓ may occur immediately without time for interfering mechanisms.

In some embodiments, after annealing under a reducing atmosphere, a discrete layer of MnOₓ may be observable. Any suitable thickness may be present. In some embodiments, this layer of MnOₓ can have a thickness of 3 nm or more, 6 nm or more, or 6 nm to 9 nm. In some embodiments, there may be little detectable (by TEM and EELS) MnOₓ region after annealing under a reducing atmosphere, although it is believed that some MnOₓ (likely in low oxidation state) remains at the glass-copper interface to mediate copper/glass bonding and enhance adhesion.

### Structure

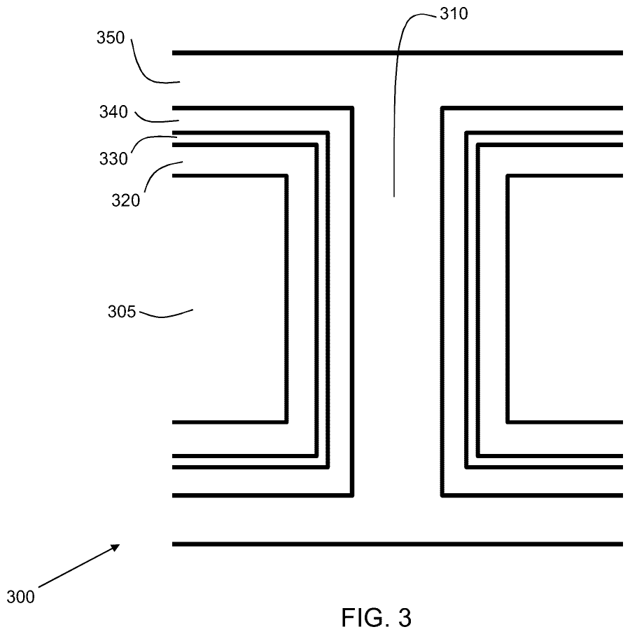

FIG. 3 shows a filled via hole structure 300 after processing as described herein. On a substrate 305 having a via hole 310 therein, the following layers are deposited, in order: an MnOₓ adhesion layer 320, a catalyst layer 330, a first layer 340 of copper, and a second layer 350 of copper. First layer 340 of copper and second layer 350 of copper fill via hole 310. MnOₓ adhesion layer 320 leads to superior adhesion of copper to substrate 305. After annealing as described herein, one or more of MnOₓ adhesion layer 320 and catalyst layer 330 may no longer exist due to diffusion. And, first layer 340 of copper and second layer 350 of copper may not be distinguishable as distinct layers.

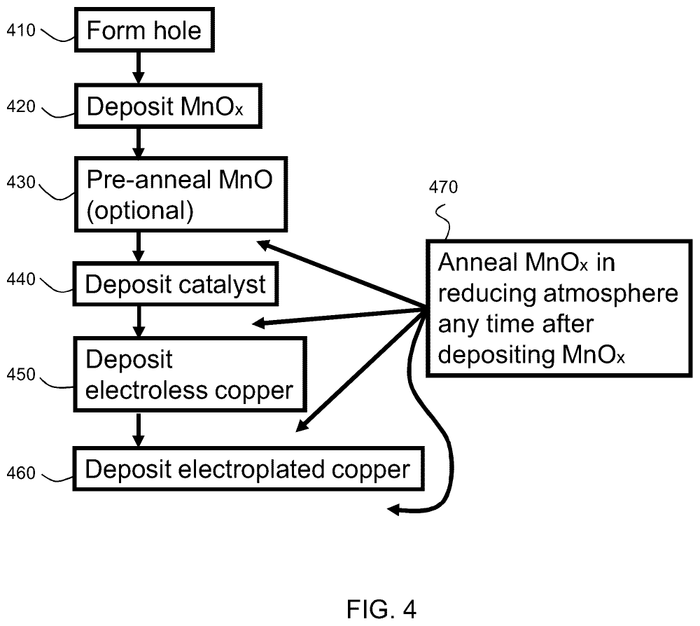

FIG. 4 shows a process flow according to some embodiments. The following steps are performed in order:
Step 410: Form hole in substrate
Step 420: Deposit MnOₓ adhesion layer
Step 430: (Optional) pre-anneal to oxidize MnOₓ
Step 440: Deposit Catalyst
Step 450: Deposit electroless copper
Step 460: Deposit electroplated copper

At any point after the MnOₓ adhesion layer is deposited, and after the optional pre-anneal (if performed), the MnOₓ adhesion layer is annealed under a reducing atmosphere. Without being limited by theory, it is believed that this anneal reduces at least some of the MnOₓ to a lower oxidation state at the copper—MnOₓ interface, and that this reduced MnOₓ enhances adhesion.

### EXPERIMENTAL

### Adhesion

Adhesion tests were performed on copper layers deposited as described herein. Adhesion was tested using a 5N/cm tape test according to ASTM standard D3359 cross hatch tape test. While the samples tested for adhesion were planar, and the copper was not deposited on the interior surface of a via, the tests are indicative of copper adhesion to the interior surface of a via.

### Example 1

A sample was prepared as follows:
a 10 nm thick layer of MnOₓ was deposited on a planar cleaned EXG (Eagle XG®, available from Corning, Inc.) glass substrate by e-beam evaporation
the MnOₓ and glass substrate were thermally treated at 400° C. under vacuum for 30 minutes to improve the adhesion between glass surface and MnOₓ.
palladium catalyst was deposited
a 150 nm thick first layer of copper was deposited via electroless deposition using the palladium catalyst. The deposition rate was about 100 nm/min.
the sample was annealed in a reducing atmosphere (forming gas, 4% H₂ and 96% N₂) at 400° C. for 10 minutes
a 3 μm thick second layer of copper was deposited using electroplating
the samples were thermally treated at 350° C. under vacuum was performed to remove any intrinsic stress in the electroplated copper.

An ASTM standard D3359 cross hatch tape test was performed on the sample of Example 1, using tape with a 5 N/cm adhesion strength towards a copper block. The simplest version of the test was used—a piece of tape was pressed against the cross hatched film stack, and the degree of coating removal was observed when the tape is pulled off. Unless otherwise specified, this same test is used to measure adhesion throughout. Example 1 passed the 5 N/cm adhesion test.

### Example 2

A sample was prepared as follows:
a 10 nm thick layer of MnOₓ was deposited on a planar cleaned EXG (Eagle XG®, available from Corning, Inc.) glass substrate by PVD
the MnOₓ and glass substrate were not thermally prior to Cu deposition
a 150 nm thick first layer of copper was deposited via PVD.
the sample was not annealed in a reducing atmosphere
a 2.5 μm thick second layer of copper was deposited using electroplating
the samples were thermally treated at 350° C. under vacuum was performed to remove any intrinsic stress in the electroplated copper.

Example 2 passed the 5 N/cm adhesion test.

### Example 3

A sample was prepared as follows:
a 10 nm thick layer of MnOₓ was deposited on a planar cleaned EXG (Eagle XG®, available from Corning, Inc.) glass substrate by PVD
the MnOₓ and glass substrate were thermally treated at 400° C. under vacuum for 30 minutes to improve the adhesion between glass surface and MnOₓ.
palladium catalyst was deposited
a 150 nm thick first layer of copper was deposited via electroless deposition using the palladium catalyst. The deposition rate was about 100 nm/min.
the sample was annealed in a reducing atmosphere (forming gas, 4% H₂ and 96% N₂) at 400° C. for 10 minutes
a 2.5 μm thick second layer of copper was deposited using electroplating
the samples were thermally treated at 350° C. under vacuum was performed to remove any intrinsic stress in the electroplated copper.

Example 3 passed the 5 N/cm adhesion test.

Examples 2 and 3 were evaluated using TEM (Transmission Electron Microscopy) and EELS (Electron Energy Loss Spectroscopy).

FIG. 5 shows a TEM image 510 of Example 2, and a TEM image 520 of Example 3. In FIG. 5 (only), the label “MnO” is used to mean MnOₓ. This usage of MnO in FIG. 5 only is a deviation from the normal use of MnO herein to refer to a specific oxidation state. Image 510, for a sample not annealed in a reducing atmosphere, shows an MnO thickness of 9 nm, whereas image 520, for a sample annealed in a reducing atmosphere, shows an MnO thickness of only 6 nm. A comparison of image 510 to image 520 shows that exposure to a reducing atmosphere has an effect on the MnO layer. There was a difference between Example 2 and Example 3 in addition to the anneal under reducing atmosphere. Specifically, the copper seed layer of Example 2 was deposited by PVD, whereas the copper seed of Example 3 was deposited by electroless plating. But, this difference in deposition method is not expected to have a significant effect on the MnOₓ layer thickness.

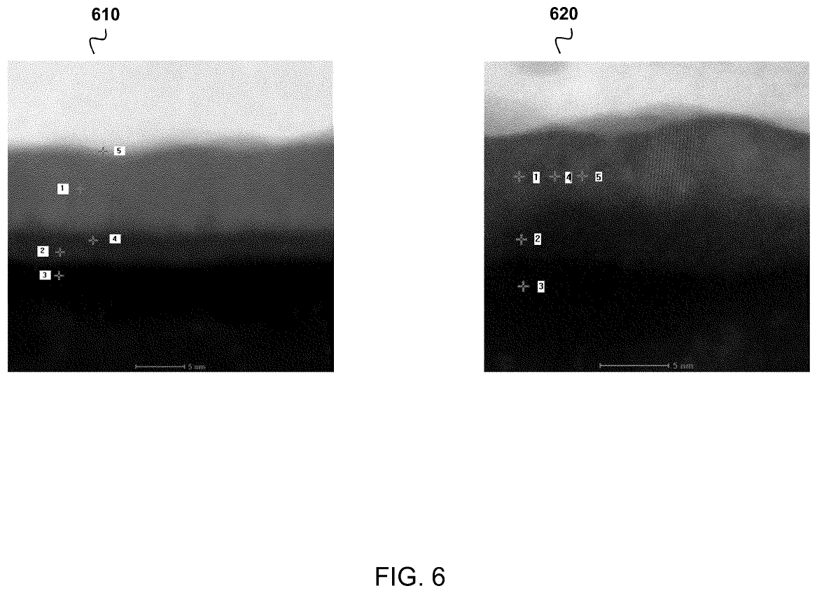

FIG. 6 shows a TEM image 610 of Example 2, and a TEM image 620 of Example 3. The numbered crosses in FIG. 6 denote locations where EELS analysis was carried out to determine composition through Mn oxidation state. In image 610, the numbers correspond to:
1: Mn₃O₄
2: Mn₂O₃ (minor*)+Mn₃O₄ (minor)+SiO₂
3: SiO₂
4: Mn₂O₃ (minor)+Mn₃O₄ (minor*)+SiO₂
5: Mn₃O₄
   The EELS data was not analyzed quantitatively. But, it is still possible to tell something about the relative amounts of different components from the EELS data based on the shape of the signal profile, and the relative magnitude of various features in that profile. A composition without “minor” means that the signal for that composition showed up strongly and clearly in the EELS profile. A composition with a “minor” or “minor*” notation means that the signal corresponding to the composition showed up weakly in the EELS profile. With such weak signals, where different compositions may have similar EELS profiles, it can be difficult to definitively state which composition is present. But, based on other factors such as the majority component, a reasonable estimate may be made as to which component is present. Where a point indicates both “minor*” and “minor,” the minor* component likely makes more of a contribution to the weak signal in the EELS profile than the minor component. For example, at point 1, Mn₂O₃ (minor*)+Mn₃O₄ (minor)+SiO₂, means that strong contribution to the EELS signals is observed from SiO₂, and some minor MnOₓ contribution that can be a mix of different oxidation states with likely stronger Mn₂O₃ and weaker Mn₃O₄ contribution based on the signal shape. In image 620, the numbers correspond to:
1: MnO
2: Mn₂O₃ (minor)+Mn₃O₄ (minor)+SiO₂
3: SiO₂
4: MnO+Mn₃O₄ (minor*)+Mn₂O₃ (minor)
5: MnO+Mn₃O₄ (minor*)+Mn₂O₃ (minor)

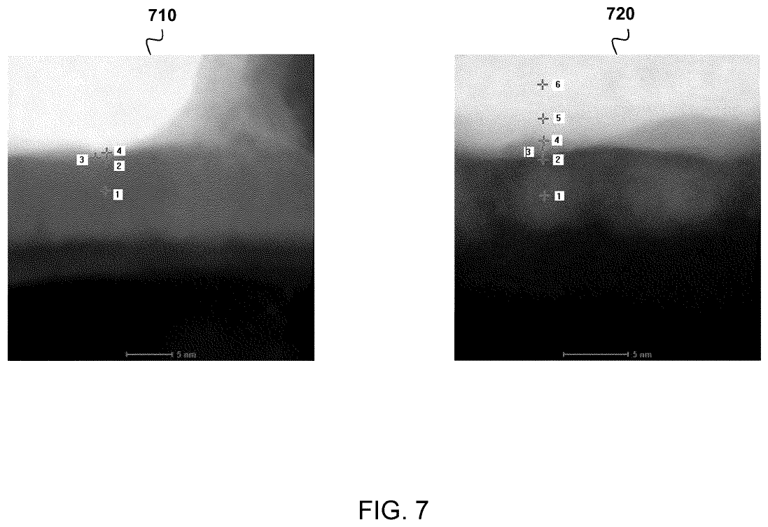

Similar to FIG. 6, FIG. 7 shows a TEM image 710 of Example 2, and a TEM image 720 of Example 3. The images of FIG. 7 were taken at a location different than those of FIG. 6. The numbered crosses in FIG. 7 denote locations where EELS analysis was carried out to determine composition. In image 710, the numbers correspond to:
1: Mn₃O₄
2: Mn₃O₄
3: Mn₃O₄
4: MnOₓ (minor)
   The strength of the Mn₃O₄ signal decreases from position 1 to position 4. Based on the image and measurements at other points, copper is present at point 4. But, copper data not specifically collected at point 4.
   In image 720, the numbers correspond to:
1: MnO
2: MnO+Mn₃O₄ (minor)
3: MnO+Mn₃O₄ (minor)
4: MnO+Mn₃O₄ (minor)
5: MnOₓ (minor)
6: MnOₓ (minor)
   The indication MnOₓ in the point EELS signal descriptions above means that the MnOₓ signal is overall so weak that it is impossible to decipher signal shape differences arising from different oxidation states of Mn. Similar to image 710, in image 720, copper is present at points 3, 4, 5 and 6. But, copper data not specifically collected at those points.

MnOₓ deposited by PVD under the conditions used for Examples 2 and 3 is mostly Mn₃O₄. The EELS measurements of FIG. 6 and FIG. 7 show that Example 2, which was not annealed under a reducing atmosphere, remains mostly Mn₃O₄. Example 3, by contrast, shows a significant amount of MnO. It is believed that this MnO was formed due to annealing under a reducing atmosphere.

### Examples 4-9

Examples 4-9 were prepared as indicated in Table 1.

TABLE 1

| | | | | | Anneal | | | |
|---|---|---|---|---|---|---|---|---|
| | | | | | H₂(5%)/ | | | |
| | MnOₓ | | | | N₂ | | | 5N/cm |
| | thickness/ | pre- | | 1^{st} layer | Atmo- | | 2^{nd} layer | tape |
| Ex. | nm | anneal | | of Cu | sphere | | of Cu | test |
| 4 | PVD 10 | No | | electroless | 400° | C. | No | pass |
| | | | | 150 nm | 10 | min | | |
| 5 | PVD 10 | No | | electroless | 400° | C. | electroplate | fail |
| | | | | 150 nm | 10 | min | 3 μm | |
| 6 | PVD 10 | 400° | C. | electroless | 400° | C. | No | pass |
| | | 30 | min | 150 nm | 10 | min | | |
| 7 | PVD 10 | 400° | C. | electroless | no | | No | partial |
| | | 30 | min | 150 nm | | | | fail |
| 8 | PVD 10 | 400° | C. | electroless | no | | electroplate | fail |
| | | 30 | min | 150 nm | | | 3 μm | |
| 9 | PVD 10 | 400° | C. | electroless | 400° | C. | electroplate | pass |
| | | 30 | min | 150 nm | 10 | min | 3 μm | |

Each of examples 4-9 were prepared on Eagle XG® glass. Each example had 10 nm of MnOₓ deposited by PVD. Then, some of the examples were exposed to a pre-anneal at 400° C. for 30 min under ambient conditions, i.e., oxidizing conditions. Some examples were not pre-annealed, as indicated in Table 1. Each example then had a 1^{st} layer of copper deposited to a thickness of 150 nm using electroless deposition. Then, some of the examples were annealed under a reducing atmosphere (forming gas) at 400° C. for 10 min, as indicated in Table 1. Then, some of the examples had a 3 μm thick second layer of copper deposited by electroplating. Each example was tested using a 5N/cm tape test. Some examples passed and some failed, as indicated in Table 1.

The most significant point of Table 1 can be seen from comparing Example 8 to Example 9. These two examples have both the first and second layer of copper deposited. As such, they most closely correspond to a real-world application for copper adhered to glass. The only difference in the preparation of Example 8 and Example 9 is that Example 9 was exposed to a reducing atmosphere, whereas Example 8 was not. Example 8 failed the tape test, while Example 9 passed. Examples 8 and 9 demonstrate that annealing in a reducing atmosphere improves adhesion of copper to glass when using an MnO adhesion layer.

Comparing Example 5 (fail) to Example 9 (pass) shows that the pre-anneal also improves adhesion.

Examples 4, 6 and 7 lack the 2^{nd} layer of copper. A thin layer of electroless copper alone typically adheres better than a comparable sample with an additional thick layer of electroplated copper. So, a “pass” result for a sample with only a thin layer of electroless copper does not necessarily indicate that the sample will have suitable adhesion after a thick layer of electroplated copper is added. And, such a thin layer alone is generally not sufficiently conductive for use in a via. Nevertheless, comparing examples 4, 6 and 7 shows that annealing under a reducing atmosphere improves adhesion. Comparing example 4 to example 7 shows that the anneal under reducing atmosphere has a larger effect on improved adhesion than the pre-anneal.

The two full stacks that were subject to anneal under a reducing atmosphere (Examples 5 and 9) were subject to an EELS analysis. No discrete/well-defined MnOₓ or MnO layer was detected by TEM imaging. A small Mn signal was detected at the glass—copper interface (by energy dispersive x-ray spectroscopy). Without being bound by theory, it is believed that exposure to a reducing atmosphere locks in an oxidation state for MnO at the copper interface that is favorable to adhesion. But, the remainder of the Mn may diffuse into the copper, which may also improve adhesion.

### CONCLUSION

Those skilled in the relevant art will recognize and appreciate that many changes can be made to the various embodiments described herein, while still obtaining the beneficial results. It will also be apparent that some of the desired benefits of the present embodiments can be obtained by selecting some of the features without utilizing other features. Accordingly, those who work in the art will recognize that many modifications and adaptations are possible and can even be desirable in certain circumstances and are a part of the present disclosure. Therefore, it is to be understood that this disclosure is not limited to the specific compositions, articles, devices, and methods disclosed unless otherwise specified. It is also to be understood that the terminology used herein is for the purpose of describing particular embodiments only and is not intended to be limiting. Features shown in the drawing are illustrative of selected embodiments of the present description and are not necessarily depicted in proper scale. These drawing features are exemplary, and are not intended to be limiting.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or description that the steps are to be limited to a specific order, it is no way intended that any particular order be inferred.

Unless otherwise expressly stated, percentages of glass components described herein are in mol % on an oxide basis. Unless otherwise expressly stated, percentages of gaseous compositions are in vol %.

The specification describes to a thin first layer of copper and a thick second layer of copper. While copper is preferred in some embodiments and may have unique issues and properties relating to bonding to glass and the use of MnOₓ as an adhesive layer, this description should be understood as encompassing other embodiments using other conductive metals that are difficult to bond directly to glass, such as silver, gold and other conductive metals.

It will be apparent to those skilled in the art that various modifications and variations can be made without departing from the spirit or scope of the illustrated embodiments. Since modifications, combinations, sub-combinations and variations of the disclosed embodiments that incorporate the spirit and substance of the illustrated embodiments may occur to persons skilled in the art, the description should be construed to include everything within the scope of the appended claims and their equivalents.

What is claimed is:

1. An article comprising:
a substrate comprised of glass or glass ceramic;
an adhesion layer on the substrate, the adhesion layer comprising manganese oxide (MnOₓ), and the manganese oxide directly contacting the glass or glass ceramic; and
a copper layer deposited on the adhesion layer,
wherein the adhesion layer comprises an oxidation gradient such that the adhesion layer has a relatively higher oxidation state adjacent to the substrate and a relatively lower oxidation state adjacent to the copper layer.

2. The article of claim 1, wherein the substrate is comprised of fused silica glass, aluminoborosilicate glass, or the glass ceramic, and the manganese oxide directly contacts the fused silica glass, the aluminoborosilicate glass, or the glass ceramic.

3. The article of claim 1, wherein substrate is comprised of fused silica glass or aluminoborosilicate glass, and the manganese oxide directly contacts the fused silica glass or the aluminoborosilicate glass.

4. The article of claim 1, wherein the adhesion layer consists essentially of the manganese oxide.

5. The article of claim 1, wherein the adhesion layer adjacent to the substrate with the relatively higher oxidation state comprises MnO₂, and the adhesion layer adjacent to the copper layer with the relatively lower oxidation state comprises MnO.

6. The article of claim 1, wherein the substrate comprises a via hole formed through the substrate, and the adhesion layer is on an interior surface of the via hole.

7. The article of claim 6, wherein the via hole comprises a first opening on a first surface of the substrate and a second opening on a second surface of the substrate and a waist between the first opening and the second opening, the waist comprising a diameter that is at least 70% of a diameter of the first opening or the second opening.

8. The article of claim 6, wherein the via hole has an aspect ratio from about 1:1 to about 10:1.

9. The article of claim 8, wherein the aspect ratio of the via hole is from about 2:1 to about 9:1.

10. The article of claim 1, wherein the adhesion layer has a thickness of about 3 nm or more.

11. The article of claim 10, wherein the thickness of the adhesion layer is about 6 nm or more.

12. The article of claim 11, wherein the thickness of the adhesion layer is from about 6 nm to about 9 nm.

13. The article of claim 1, wherein the copper layer has a thickness from about 1 micron to about 100 microns.

14. The article of claim 1, wherein:
the substrate is comprised of fused silica glass or aluminoborosilicate glass, the manganese oxide directly contacting the fused silica glass or the aluminoborosilicate glass,
the adhesion layer consists essentially of the manganese oxide, and
the substrate comprises a via hole formed through the substrate, the adhesion layer being on an interior surface of the via hole.

15. The article of claim 14, wherein the adhesion layer adjacent to the substrate with the relatively higher oxidation state comprises MnO₂, and the adhesion layer adjacent to the copper layer with the relatively lower oxidation state comprises MnO.
